(19) United States
(12) Patent Application Publication
(10) Pub. No.: US 2006/0253749 A1
(43) Pub. Date: Nov. 9, 2006

(54) Real-time memory verification in a high-availability system

(75) Inventors: Alfredo Alderegula, Cary, NC (US); William Edward Atherton, Hillsborough, NC (US); Marcus Alan Baker, Apex, NC (US); Sheldon Jay Sigrist, Cary, NC (US); Jeffrey B. Williams, Raleigh, NC (US)

Correspondence Address: IBM CORPORATION, PO BOX 12195, DEPT YXSA, BLDG 002, RESEARCH TRIANGLE PARK, NC, 27709, US

(73) Assignee: International Business Machines Corporation, Armonk, NY (US)

(21) Appl. No.: 11/124,745

(22) Filed: May 9, 2005

(51) Int. Cl. G11C 29/00

(52) U.S. Cl. 714/718

(57) ABSTRACT

A computer system includes a look-up table implemented in a memory controller which includes a processor which manipulates data and look-up-table entries so as to make an unused and in-use memory available for testing in a manner which is alien to and aims to minimize impact to the operating system and the main system processor. In-use memory is made available by moving in-use data to an unused area of memory within a bank, by moving in-use data to another bank having an unused area, or by compressing in-use data within a bank and moving the data to an area within the bank made available through such compression, and updating the look-up table to point to the moved areas so that memory references can continue to be serviced during the testing process. Areas made available can be tested by a non-system processor such as a service processor, although other processors can be used.

### BACKGROUND of the INVENTION

This invention broadly pertains to computer systems and other information handling systems and, more particularly, to a computer system in which high availability is maintained by verifying unused and in-use memory in such a way so as to minimize or eliminate impact to main CPU and operating system resources.

Computers are becoming increasingly vital to servicing the needs of business. As computer systems and networks become more important to servicing immediate needs, the availability of such systems becomes paramount. System availability is a measure of how often a system is capable of providing service to its users. System availability is expressed as a percentage representing the ratio of the time in which the system provides acceptable service to the total time in which the system is required to be operational. High-availability systems provide in excess of 99.99 percent availability which corresponds to unscheduled downtime measured in minutes per year.

In order to achieve high availability, a computer system provides means for redundancy among different elements of the system. Clustering is a method for providing increased availability. Clusters are characterized by multiple systems, or “nodes,” that work together as a single entity to cooperatively provide applications, system resources, and data to users. Computing resources are distributed throughout the cluster. Should one node fail, the workload of the failed node can be spread across the remaining cluster members.

Memory mirroring is one example of clustering. However, while memory mirroring provides a level of reliability, availability, and serviceability, it is further advantageous to pro-actively test memory components, whether they are clustered or not. To this end, real time memory diagnostics are known to be performed in the industry. With real time memory diagnostics, memory is tested while a system is fully operational. However, real time memory diagnostics require system resources to be released by the operating system to insure that the memory to be tested is not being used. Additionally, real time diagnostics are typically performed using a main processor of the computer system. Thus, disadvantageously, both operating system and main processor resources are used. Further, the process of freeing memory can require large amounts of overhead and disruption to server processes.

Further, error detection in a distributed environment has a tendency to become complex and problematic. Real time testing performed at the level of the OS and main processor involves more circuits and introduces a greater degree of uncertainty as to the origin of any found error. For example, if a link between components A and B stops sending information between components A and B, component A may not be sure if the failure originated in the link, or in component B. Similarly, component B may not be sure if the failure originated in the link, or in component A. Some errors may not be detectable within the failing component itself, but rather have to be inferred from multiple individual incidents, perhaps spanning multiple components. Additionally, some errors are not manifested as component failures, but rather as an absence of response from a component.

Within the overall computer system, external audits of individual components may, themselves, fail or fail to complete. The systems that run the error checking and component audits may fail, taking with them all of the mechanisms that could have detected the error. Therefore, having high level system components, such as the main system processor and the operating system, involved in the testing process can be both problematic and costly.

### SUMMARY of the INVENTION

What is needed, therefore, are apparatus and methods which perform the testing by introducing testing components coupled closer to the components to be tested. With closer coupling, faults can be better isolated to the memory component without implicating higher level system components such as the main system processor. Furthermore, what is needed are apparatus and methods which test memory, whether used or unused, while eliminating or minimizing impact on operating system and main processor resources. Additionally, what is needed are systems and methods which test in-use memory while minimizing or eliminating disruption to the system. According to various embodiments, real time testing is no longer performed by higher-level system components which require system memory to be released by the operating system. Thus the process of freeing memory through the OS, which requires large amounts of overhead and disruption to server processes, is evaded.

As will be seen, the embodiments disclosed satisfy the foregoing needs and accomplish additional purposes. Briefly described, the present invention provides methods and systems which relocate data contained in a first memory area to a second memory area, service memory references directed to the first memory area from the second memory area, and pass test data to the first memory area for testing at least a portion of the first memory area.

It has been discovered that the aforementioned challenges are addressed using apparatus and methods which include, in certain embodiments, a lookup table in a memory controller having processing capability for programming the lookup table and relocating, servicing, and passing test data to the memory. In these embodiments, placing the lookup table and processing capability within the memory controller closely couples these circuits to the memory to be tested. Embodiments of the invention include embodiments in which data is compressed/decompressed in conjunction with the relocation.

According to one aspect of the present invention, a system includes a first memory area and a second memory area and a main processor which runs an operating system from one or more of the memory areas. The system further includes a memory controller which couples the main processor to the first memory area and the second memory area. The memory controller includes processing capability which is able to operate in a mode which is alien to the operating system and is effective to (1) relocate data contained in the first memory area to the second memory area, (2) service memory references directed to the first memory area from the second memory area, and (3) pass test data to the first memory area for testing at least a portion of the first memory area.

In one embodiment, the first memory area and the second memory area are areas within one or more banks of memory which form one of at least two mirrored memory areas of a mirrored memory. In this embodiment, the one of at least two mirrored memory areas are either an active area of the mirrored memory, or a mirrored area of the mirrored memory.

A methodical aspect of the present invention includes relocating data contained in a first memory area to a second memory area, servicing memory references directed to the first memory area from the second memory area, and testing at least a portion of the first memory area.

Techniques described herein are suitable for use in standard memories and in memory-mirrored arrangements. The memory areas referred to herein may, but do not necessarily, correspond to the memory banks of a mirrored memory configuration.

Systematic and methodical aspects can include the generation of a failure signal which identifies a fault in relation to a bank under test such as an active bank. The aspects can further include breaking the mirror between the active and mirrored bank and disabling the active bank. A predictive failure report can be sent to a management module for ultimately providing indicia to a system administrator. Aspects may employ compression as needed in either an active bank or a mirrored bank of a mirrored memory. For example, the data in a mirrored bank can be compressed into a first area within the mirrored bank (or any other bank) in order to provide enough available memory to test the mirrored bank (and visa versa with respect to active/mirrored). Data can be moved at will in support of testing.

As will be seen, optional systematic and methodical embodiments implemented according to the present invention are able to continue operating without the additional reliability, availability, and serviceability provided by memory mirroring by servicing requests from an unbroken compressed area of a broken DIMM. For example, when a first of two DIMMs dies, say the active bank, the mirrored bank is subdivided into two compressed areas comprising an active portion of the compressed mirrored bank and a mirrored portion of the compressed mirrored bank. The memory mirroring is then reestablished in these two compressed areas. If the mirrored portion of the compressed active bank dies, mirroring can be broken and system operation can continue out of the unbroken compressed area of mirrored bank. A predictive failure report is sent in both failure events.

For example, a methodical aspect can include determining a fault condition in an active bank of a mirrored memory subsystem included in a computing system during a test operation of the active bank. The mirrored memory subsystem includes the active bank and a mirrored bank. System writes are directed to both banks. System reads are serviced from the active bank during a normal mode of operation and from the mirrored bank during the test operation of the active bank. The method may include (1) generating a first failure signal which identifies a fault in relation to the active bank, (2) compressing the data in the mirrored bank into a first area within the mirrored bank, (3) duplicating the compressed data into a second area within the mirrored bank; and (4) establishing a compressed mirrored memory within the mirrored bank using the first area and the second area as corresponding symmetrical mirrored memories.

In one embodiment, system reads of a mirrored memory are primarily serviced from either the active bank or the mirrored bank during either the normal or test mode of operation. If an error is encountered, a system read is secondarily serviced from the other bank.

In one embodiment, the establishment of the compressed mirrored memory can include utilization of one of the first area and the second area as the active portion of the compressed mirrored memory and the other as the mirrored portion.

In one embodiment, system writes are directed to the active, and mirrored, portions and system reads are serviced from any of the active and mirrored portions during normal operation and from the mirrored portion during a test operation of the active portion.

In one embodiment, the previously mentioned utilization, of one of the first area and the second area as the active portion of the compressed mirrored memory and the other as the mirrored portion, can be switchable such that either area can be utilized as either portion.

In one embodiment, upon a fault being detected in any one of the active and mirrored portions, the methodical aspect further includes (1) breaking the establishment of the compressed mirrored memory, (2) generating a second failure signal in relation to the mirrored bank, and (3) continuing system operation by servicing read and write references from a compressed portion which is other than the portion for which the fault was detected.

The foregoing is a summary and thus contains, by necessity, simplifications, generalizations, and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION of the DRAWINGS

Some of the purposes of the invention having been stated, others will appear as the description proceeds, when taken in connection with the accompanying drawings, in which:

FIG. 1 is a block diagram of a computer system according to a preferred embodiment of the present invention which incorporates a lookup table within a DRAM memory controller;

FIG. 2 is a block diagram of the memory subsystem shown in FIG. 1;

FIG. 3 is a block diagram of a lookup table configured according to a preferred embodiment of the present invention as shown in FIG. 2;

FIG. 4 is a logic flow diagram depicting the actions taken by a memory controller configured according to a preferred embodiment of the present invention depending on whether a memory reference is received through a main interface or through a sideband interface;

FIG. 5 is a logic flow diagram depicting the actions taken by a service processor and a memory controller configured according to an embodiment of the present invention during a test process;

FIG. 6 is a depiction of a segment of memory configured according to an embodiment of the present invention in which an unused memory area is directly tested;

FIG. 7 is a depiction of a segment of memory configured according to an embodiment of the present invention in which an in-use memory area is tested by moving the memory area contents in a one-to-one correlation and testing the area made available as a result of the move;

FIG. 8 is a depiction of a segment of memory configured according to an embodiment of the present invention in which an in-use memory area is tested by moving the memory area contents in other than a one-to-one correlation and testing the area made available as a result of the move;

FIG. 9 is a depiction of a segment of memory configured according to an embodiment of the present invention in which an in-use memory area is tested by compressing the memory area contents and testing the area made available through such compression;

FIG. 10 is a block diagram of a mirrored memory subsystem according to an embodiment of the present invention in its normal mode of operation;

FIG. 11 is a block diagram of a mirrored memory subsystem according to an embodiment of the present invention wherein the mirroring is broken in order to test one of two memory banks;

FIG. 12 is a block diagram of a mirrored memory subsystem according to an embodiment of the present invention in which the mirroring is maintained during the testing of one of two memory banks; and

FIGS. 13-14 are block diagrams of a mirrored memory subsystem according to an embodiment of the present invention in which memory areas are found to be defective and in which an increased level of availability is provided through continuous verification of the remaining memory.

### DETAILED DESCRIPTION of the ILLUSTRATIVE EMBODIMENTS

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of this invention. Accordingly, the description which follows is to be understood as being a broad, teaching disclosure directed to persons of skill in the appropriate arts, and not as limiting upon the present invention.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

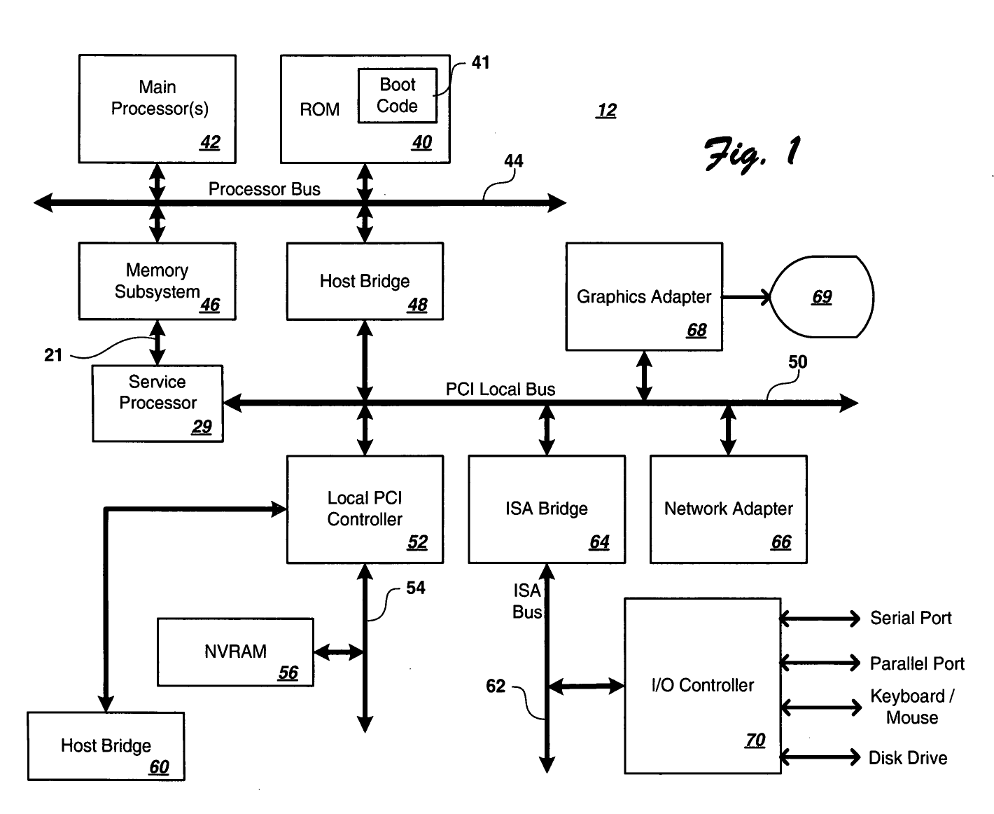

Referring now more particularly to the accompanying drawings, in which like numerals indicate like elements or steps throughout the several views, FIG. 1 is a block diagram of a computer system according to a preferred embodiment of the present invention which incorporates a lookup table within an SDRAM memory controller.

Referring now to FIG. 1, there is depicted a block diagram of an illustrative embodiment of a computer system 12. The illustrative embodiment depicted in FIG. 1 may be a desktop computer system, such as one of the ThinkCentre® or ThinkPad® series of personal computers, an xSeries Server®, or a workstation computer, such as the Intellistation®, which are sold by and are trademarks of International Business Machines (IBM) Corporation of Armonk, N.Y.; however, as will become apparent from the following description, the present invention is applicable to maintaining the availability of a data processing system and testing memory subcomponents with little or no impact on the main processor and/or the operating system.

As shown in FIG. 1, computer system 12 includes at least one main processor 42, which is coupled to a Read-Only Memory (ROM) 40 and a memory subsystem 46 by a processor bus 44. Main processor 42, which may comprise one of the PowerPC™ line of processors produced by IBM Corporation, is a general-purpose processor that executes boot code 41 stored within ROM 40 at power-on and thereafter processes data under the control of operating system and application software stored in memory subsystem 46. Main processor 42 is coupled via processor bus 44 and host bridge 48 to Peripheral Component Interconnect (PCI) local bus 50.

PCI local bus 50 supports the attachment of a number of devices, including adapters and bridges. Among these devices is network adapter 66, which interfaces computer system 12 to LAN 10, and graphics adapter 68, which interfaces computer system 12 to display 69. Communication on PCI local bus 50 is governed by local PCI controller 52, which is in turn coupled to non-volatile random access memory (NVRAM) 56 via bus 54. Local PCI controller 52 can be coupled to additional buses and devices via a second host bridge 60.

Computer system 12 further includes Industry Standard Architecture (ISA) bus 62, which is coupled to PCI local bus 50 by ISA bridge 64. Coupled to ISA bus 62 is an input/output (I/O) controller 70, which controls communication between computer system 12 and attached peripheral devices such as a keyboard, mouse, and a disk drive. In addition, I/O controller 70 supports external communication by computer system 12 via serial and parallel ports.

Service processor 29 performs a variety of system functions including the testing of system SDRAM in one embodiment. In order to affect the testing of the SDRAMs, service processor 29 is coupled to the memory subsystem 46 through a high-speed sideband interface 21. In the preferred embodiment, high-speed sideband interface 21 is implemented as an Intel i486 interface in order to make use of existing macros which are readily available in the industry. In one alternative embodiment, an I2C interface can be used where low-cost is preferred over high-speed. In another alternative embodiment, a JTAG interface can be used where a higher speed serial interface is desired. In addition to the testing of system SDRAM, which will be described in more detail as the description ensues, service processor 29 is provided with auxiliary power even while computer system 12 is powered down. This allows service processor 29 to respond to wake-on-LAN events and power-on the system and perform administrative functions at times determined by an administrator.

FIG. 2 is a block diagram of memory subsystem 46 shown in FIG. 1. Memory subsystem 46 includes a memory controller portion 102 and two banks of SDRAM 100 and 101 and is able to utilize SDRAM banks 100 and 101 in either a standard configuration or in a memory mirrored configuration. The memory controller portion 102 of memory subsystem 46 includes two main interfaces. The first is SDRAM interface 94 which interfaces to SDRAM banks 100 and 101, and the second is dual ported interface 81 which interfaces to various processors within the system as shall be described in more detail as the description of the embodiment ensues.

SDRAM interface 94 includes SDRAM data drivers 95, SDRAM address drivers 96, and SDRAM control drivers 97 which provide the low-level I/O interface to the SDRAMs through memory bus 104 and control lines 103 for executing memory bus cycles under the control of control circuitry 84 and lookup table 88. Control lines 103 are specific to each bank/DIMM/chip and include non bused lines such as chip select, output enable, row address select, column address select, etc.

Dual ported interface 81, as the name implies, includes two independent processor interfaces: a main processor interface 82 for coupling to main processor 42 through processor bus 44, and a sideband interface 83 for coupling to service processor 29 over high-speed interface 21. Arbitration between memory references received by the two processors is provided as described herein.

Address mux 92 subdivides the address provided by either processor into the two addresses used to address SDRAMs during each of a row address strobe phase, in which upper-level address bits are specified, and a column address strobe phase, where lower-level address bits are specified, to form a complete memory bus cycle. The subdivided addresses of each phase are referred to as muxed addresses. The muxed addresses generated by address mux 92 are passed to lookup table 88 for possible translation during the row address strobe phase.

The operation of lookup table 88 is controlled at a high level by control circuitry 84 through interface 99. Although the operation of lookup table 88 will be described in more detail, it is worthwhile to note at this stage of the description that lookup table 88 is bypassed during the column address strobe phase of a memory bus cycle.

Control circuitry 84 operates to control both high-level and low-level functions of the memory controller for gaining access to the SDRAM banks in servicing memory references received from either processor interface. Control circuitry 84 includes a memory integrity processor 85 which controls the overall high-level state machine for the memory controller and supports memory-test commands as will be described in more detail, and a memory controller state machine 86 which controls the overall low-level state machine for the memory-controller components. Memory controller state machine 86 handles high-speed state machine requirements while the memory integrity processor 85 handles other state machine requirements.

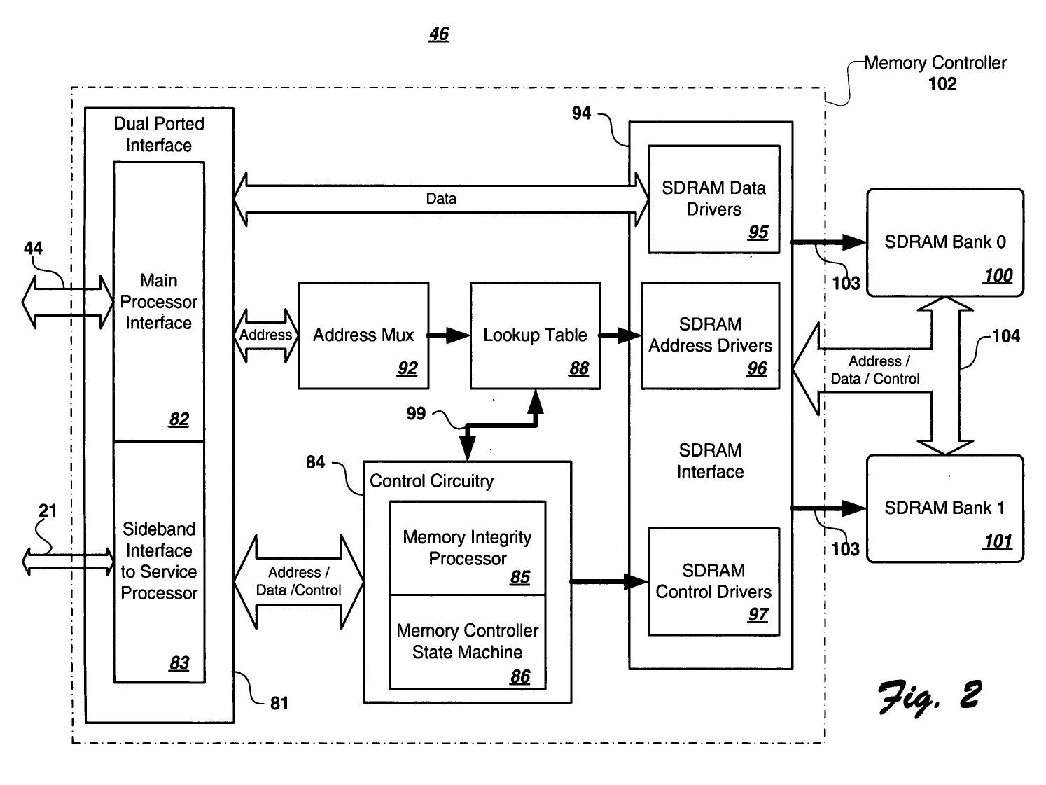

FIG. 3 is a block diagram of lookup table 88 configured according to a preferred embodiment of the present invention as shown in FIG. 2. FIG. 3 shows a first array of sixteen address translation circuits designated in FIG. 3 as range0-range15, which comprise lookup table 88. Three other identical arrays (not shown), are also included in lookup table 88 for a total of 64 address translation circuits (address translators).

Each address translator includes a translation register 115 which is preloaded by memory integrity processor 85 to include the address value to which a predetermined most-significant portion of the muxed address is to be translated during row address strobe. The remaining portion of the muxed address which is other than the predetermined most significant portion, i.e. the least significant portion of the muxed address, is combined at mux/combiner 125 under circumstances such as a hit condition to form the output of lookup table 88.

Each address translator includes a range comparator 114 which identifies a potential hit condition and enables translation register 115 when the most significant bits of the muxed address falls within the range established by range registers 110 and 111. Range registers 110 and 111 are also preloaded by memory integrity processor 85 to include the low address at register 111 and high address at register 110 for the range in which translation is specified. The operation and use of these registers will be described in relation to the figures and description which follow.

In addition to the address translation circuits, lookup table 88 includes two registers which further define a hit condition. These two registers are shown and designated as Hit{0 . . . 15} and Active{0 . . . 15} and each contain one bit which corresponds to each of the translation circuits range0-range15. Each additional array of translation circuits includes a corresponding pair of Hit and Active registers (not shown). Memory integrity processor 85 maintains the bit values of register Active{0 . . . 15} to indicate which of the 16 translation circuits range0-range15 contain active register values. Range comparators 114 maintain the bit values of register Hit{0 . . . 15} to indicate a hit condition which occurs when a current multiplexed address during row address strobe falls between the address values loaded in registers 110 and 111. Lookup table logic 121 includes low-level logic which includes the Hit and Active registers as variables for each of the translation circuits and controls the function of mux/combiner 125 for each of the arrays in combining upper-level translated address bits with lower-level muxed address bits. A hit condition at range comparator 114 enables the output of translation register 115 and asserts the appropriate bit in the Hit register. Lookup table logic 121 determines if the corresponding bits of both the Hit and Active registers are asserted, and if so, either disregards the hit and bypasses the lookup table or multiplexes and combines the high-level address bits with the low-level address bits to form a complete translated address which is output from mux/combiner 125 to the SDRAM drivers 96.

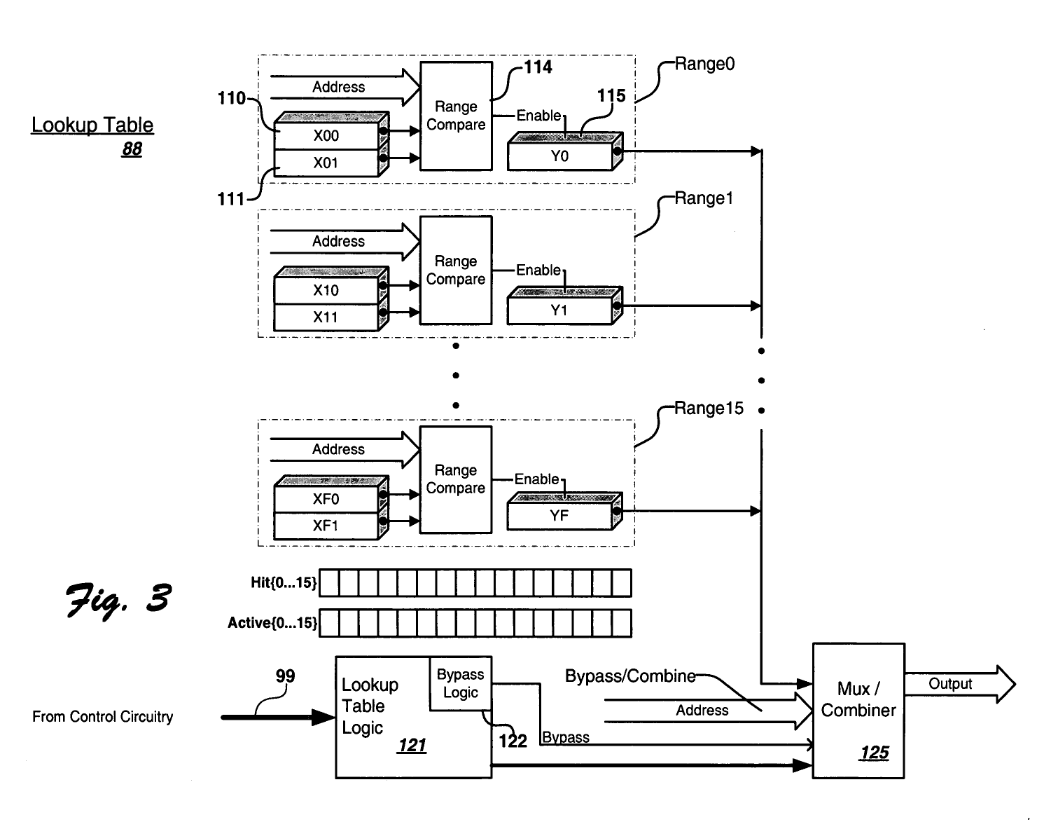

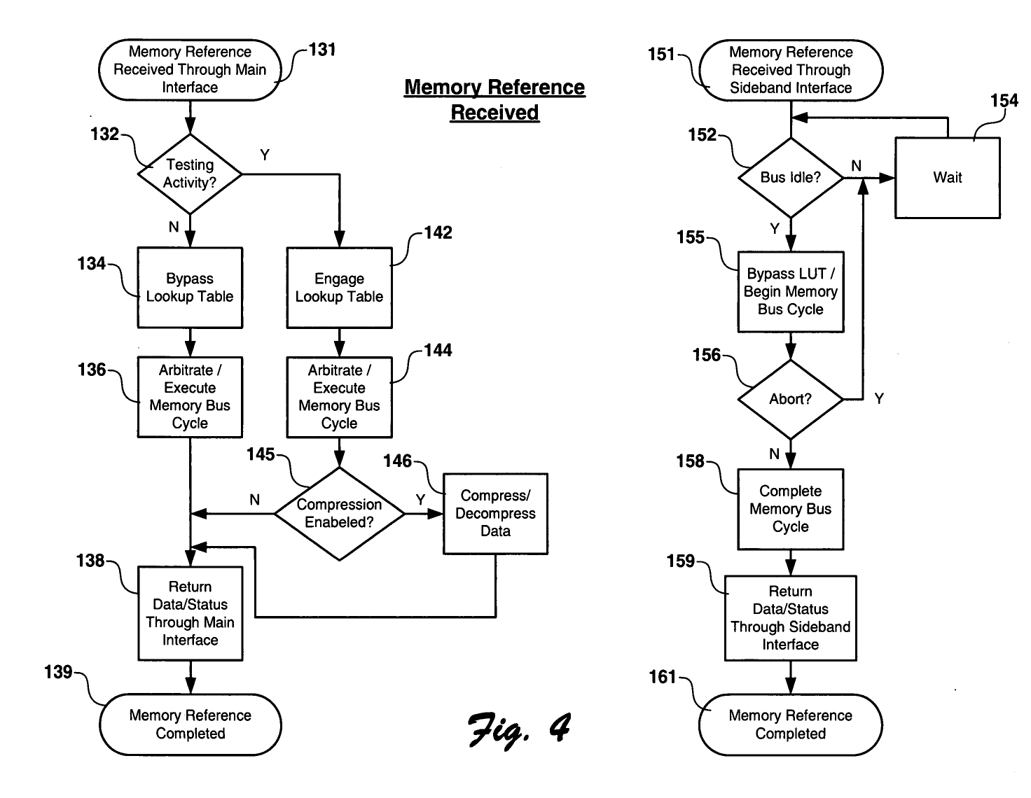

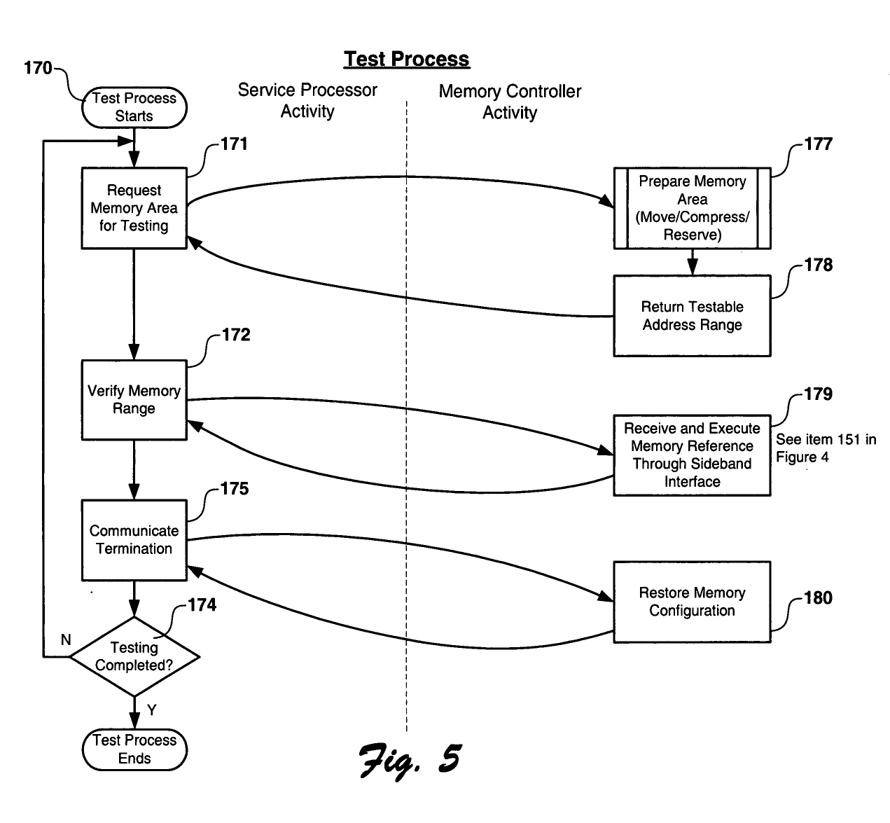

The conditions under which the hit condition is disregarded or bypassed is determined at a low level by bypass logic 122 and established at a high level by control circuitry 84 and memory integrity processor 85 shown in the previous figure. These conditions will be described in further detail with reference to FIG. 4. However, at a low level, bypass logic 122 functions to bypass lookup table 88 if either the Hit or the Active register is deasserted, or during column address strobe, or during a condition predicated by control circuitry 84 and/or memory integrity processor 85 through interface 99.

For each translation circuit, range comparator 114 determines a hit condition when the muxed address falls between a range which is greater than or equal to the value stored in range register 111 and less than or equal to the value stored in the range register 110. When a one-to-one correspondence between areas to be translated in memory is desired, relatively few translation circuits are required and a large area of memory can be translated by using an appropriate number of registers. Other configurations will be described including one-to-several and “one-to-fewer.”

Mux/combiner 125 includes a masking register (not shown) whose value is preset by memory integrity processor 85 to indicate which of the upper-level bits of translation register 115 are significant. During a translation by lookup table 88, the significant upper-level bits are then combined with the remaining bits taken from the muxed address to form a complete translated address for output to SDRAM address drivers 96. This arrangement allows for a variable length of the areas to be translated. Where a bypass signal is asserted by bypass logic 122, mux/combiner 125 acts as a multiplexer and passes the entire muxed address to the output—effectively bypassing lookup table 88.

FIG. 4 is a logic flow diagram depicting the actions taken by the memory controller depending on whether a memory reference is received through a main interface or through a sideband interface. In a first case where a memory reference is received 131 through the main processor interface 82, a first determination 132 is made as to whether any testing activity is currently underway. In the preferred embodiment, testing activity is underway if service processor 29 requests test services from memory subsystem 46 and memory integrity processor 85 has initiated address translation or the manipulation of data in SDRAM banks 100 and 101. Where no testing is currently taking place, lookup table 88 is bypassed 134. Memory controller 102 under the control of control circuitry 84 then arbitrates 136 for the memory bus and executes the memory bus cycle as normal. Main processor interface 82 returns 138 data in the case of a read reference or conveys status in the case of a write reference to main processor 42 through processor bus 44 and the memory reference is thereby completed 139.

Where it is determined 132 that testing activity is taking place, lookup table 88 is conditionally engaged 142 as previously described (row address strobe, hit, etc.). Memory controller 102 then arbitrates 144 for the memory bus and executes the multiphase memory bus cycle. Only here, the arbitration additionally includes arbitrating amongst a potentially executing test cycle. Where a test cycle is currently underway, the test cycle is immediately aborted to give priority to the memory reference received through main interface 82. A determination 145 is then made as to whether compression is enabled in the translated area of memory. If the data is translated it is decompressed/compressed 146 and returned 138 through the main interface 82 along with status in the case of a read reference, or write status given in the case of a write reference and thereby completing 139 the memory reference. The compression and/or the decompression of data, which the will be described with reference to FIG. 9, is accomplished by memory integrity processor 85 and is transparent to the operating system and main processor 42.

In a second case where a memory reference is received 151 through the sideband interface 83, as in a test sequence originating at service processor 29, a first determination 152 is made as to whether the memory bus is idle. The memory bus is considered idle where main processor 42 has no active memory references pending through main interface 82 and none are queued. If the bus is not idle, memory controller 102 waits 154 for a predetermined amount of time and proceeds to determine 150 to whether the bus is idle. If the bus is determined 152 to be in an idle condition, lookup table 88 is bypassed 155 and a memory cycle is begun on the memory bus 104. Note that, normally, lookup table 88 is not invoked while memory references are serviced 151 trough sideband interface 83. Memory references received through sideband interface 83 are considered to be test data and are considered of low priority compared to memory references received through main interface 82. Thus, it is desirable to abort a bus cycle begun at 155 in the case that a memory reference is simultaneously received 131 at main interface 82. Accordingly, a determination 156 is made in cooperation with arbitration 144 as to whether the present bus cycle is to be aborted depending upon simultaneous occurrence of a memory reference received 131 through main interface 82. If arbitration 144 ensues, memory controller 102 aborts 156 the current memory bus cycle and proceeds to wait 154 for the bus to become idle 152 to retry. If arbitration 144 does not ensue, the memory bus cycle is completed 158 and data is returned 159 or status given over high-speed interface 21 by sideband interface 83, thereby completing 161 the memory reference received through the sideband interface.

A primary test mode will now be described.

FIG. 5 is a logic flow diagram depicting the actions taken by service processor 29 and memory controller 102 during a test process. Note that on the left side of FIG. 5, service processor activity is shown. Whereas, on the right side of FIG. 5, memory controller activity is shown. In a preferred embodiment, the test process begins 170 with service processor 29 requesting 171 a memory area for testing purposes. This request is sent over high-speed interface 21 to memory controller 102 and is handled internally by memory integrity processor 85. Memory integrity processor 85 then selects a suitable area of memory to test and moves 177 and/or compresses any in-use data to another area in memory, or reserves an unused area of memory in response to the request 171. Several of the scenarios will be described in the test examples provided in FIGS. 6 through 9. Once the area of memory to be tested is prepared 177, the testable address range is returned 178 to service processor 29 in order for the verification 172 of memory to begin. Service processor 29 then verifies 172 the memory by generating memory references which serve as test sequences. These test sequences are received 179 and serviced by memory integrity processor 85 according to the process shown in the previous figure starting at 151 which bypasses lookup table 88 to directly access the test areas.

If during the verification 172 a range is found to be unreliable, that range can be marked as non allocatable by memory controller 102 and the translation provided by the lookup table can be made persistent. At the same time a predictive failure report can be issued to a management module of the computer system to further increase availability. In response to receiving a predictive failure report, the management module uses known methods to inform an administrator of the particular memory module which needs to be replaced. In the interim between the time the predictive failure report is issued and the time the part is replaced, the translation provided by the lookup table is maintained and thereafter reset. During the interim, the persistent translation circuits are no longer available. Until the part is replaced, physical OS memory references to the unreliable memory are translated by lookup table 88 to the moved and/or compressed area.

In the process of moving 177 or compressing data in order to make in-use memory areas available for testing, memory integrity processor 85 programs the various registers in lookup table 88 so that physical addresses received by the operating system/main processor 42 through processor bus 44 and main processor interface 82 are properly translated to the moved 177 or compressed areas while the original areas are tested. As previously described, where the data is in a compressed format or destined for compression, the data is first decompressed or compressed as needed by memory integrity processor 85 using an integrated version of the CRAM encoder/decoder available from IBM and referred to, for example, by D. J. Craft, “A Fast Hardware Data Compression Algorithm and Some Algorithmic Extensions,” IBM Journal of Research and Development, Volume 42, Number 6, 1998. Although a hardware implementation is preferred for speed, where cost is an important factor, a software implementation can be used using the same algorithms. Other algorithms can be used besides those used in the CRAM encoder/decoder. For example, the algorithms licensed by Stac Electronics or other Lempel-Ziv algorithms which are the well-known in the art can be used. Details concerning compression and decompression are well known in the art and are omitted so as to not obfuscate the present disclosure in unnecessary detail.

Once a given section of memory has been tested 172, the completion is communicated 175 to the memory controller/memory integrity processor 85. In response, memory integrity processor 85 “restores” 180 the memory configuration back to the area that the data originally occupied including any updates made during the time of testing through main interface 82, translated by lookup table 88, and optionally thereinto compressed.

A determination 174 is then made by service processor 29 as to whether the testing is completed for all of memory. Service processor 29 keeps track of all of the areas of memory which have been tested thus far in the process begun at 170. If testing is not complete, testing continues by requesting 171 the next memory area for testing. Where a determination 174 is made that testing has completed, that is, all of memory has been tested, the test process ends.

Various testing scenarios will now be described.

FIG. 6 is a depiction of a segment of memory configured according to an embodiment of the present invention in which an unused memory area is directly tested. Shown in FIG. 6 are various memory areas segmented according to the size programmed into the mask register of lookup table 88 (this is a variable size and is a function of the value stored in the mask register). Area 191 represents an unused area of memory which is to be tested. In this example, Service processor 29 follows OS memory allocation commands and determines which areas of memory are unallocated and are therefore available. Alternatively, this function of following OS memory allocations can be performed by memory integrity processor 85. Although this area can be treated as an in-use memory and moved or compressed as previously described, direct testing of area 191 is performed in one of several ways. Firstly, area 191 can be tested by service processor 29 and aborted if an OS memory allocation command includes area 191. Otherwise, area 191 can be reserved from allocation and then restored into the memory space upon completion of the test. Lookup table 88 is not used in this example.

FIG. 7 is a depiction of a segment of memory configured according to an embodiment of the present invention in which an in-use memory area is tested by moving the memory area contents in a one-to-one correlation and testing the area made available as a result of the move. In this example, the area shown as 194 is an area of memory which is in use by the operating system prior to the time of testing. Area 192 is free and available prior to the time of testing. Memory integrity processor 85 moves the data from area 194 to area 192 in preparation for the testing of area 194. Once the data has been moved, memory integrity processor 85 programs lookup table 88 so as to redirect OS traffic to area 192 during the test process. In this example, a one-to-one correspondence exists between area 194 and 192; both areas are of the same size and start and end as a contiguous area in memory. The size of the segments shown in the example of FIG. 7, as in FIG. 6, is less than or equal to a range size which is fully addressable by one of translation registers 115 and the mask register. In other examples where the memory area to be tested is larger than the area of translation registers 115, multiple translation circuits (range0-range15) and multiple arrays of translation circuits can be used. Thus, in this example where a one-to-one correlation exists, memory integrity processor 85 programs range registers 110 and 111 with the start and end values of area 194. Translation register 115 is programmed/set to point to the start address of area 192 and the mask register (not shown) programmed such that mux/combiner 125 combines the most significant bits of translation register 115 with the least significant bits of the muxed address. The mask, when active, acts to block bits from the translation register and pass or combine low order bits from the muxed address for those bits which are asserted in the mask. The mask value corresponds to those bits which are subject to change from the beginning to the end of the range denoted as area 194. Bits not asserted in the mask correspond to high order address values which are common to both the value stored in range register 110 and range register 111 and unchanged from the beginning to the end of area 194. Bit 0 of the active{0 . . . 15} register is asserted to enable translation.

As previously described, once the table has been filled and enabled for operation, OS memory references are redirected to area 192. That is, physical addresses originating at main processor 42 and received through processor bus 44 and main interface 82 are translated by engaging lookup table 88 as programmed by memory integrity processor 85. Meanwhile, test memory references originating at service processor 29 through high-speed interface 21 and sideband interface 83 bypass the lookup table and directly access area 194.

When testing of area 194 reaches completion, memory integrity processor 85 moves the data in area 192, now presumably updated, to area 194 as part of restoring the memory configuration to that configuration which existed prior to the test. Memory integrity processor 85 then deactivates the lookup table and thereby restoring the memory configuration. Deactivation is accomplished by deasserting appropriate bits in the active{0 . . . 15} register for those translation circuits used, in this case bit0 which corresponds to range0. Testing can then continue or, if the testing shown in FIG. 7 is the last test of a series, testing reaches completion.

FIG. 8 is a depiction of a segment of memory configured according to an embodiment of the present invention in which an in-use memory area is tested by moving the memory area contents in other than a one-to-one correlation and testing the area made available as a result of the move. In this example, an in-use area, 196, is to be tested and presumably there is insufficient contiguous area available in memory for testing. Memory integrity processor 85 moves the in-use data contained in area 196 to two half-size areas 198 and 199. Two translation circuits are required for this configuration, range0-range1. Memory integrity processor 85 programs range registers 110 and 111 in each of translation circuits range0-range1 to the beginning and ending addresses of areas 198 and 199. Each of translation registers 115 of translation circuits range0-range1 are programmed to correspond to the most significant bits of each of areas 198 and 199 in the manner previously described with reference to FIG. 7. The mask register of mux/combiner 125 is programmed to accommodate the smaller size each of the areas 198 and 199 and the appropriate bits of the active{0 . . . 15} register asserted (i.e., bits 0-1).

With this configuration, memory references received from the operating system are redirected to areas 198 and 199 as appropriate; memory references received from service processor 29 for testing purposes directly access area 196. Area 196 is tested and the memory configuration is restored as previously described upon completion of the test.

FIG. 9 is a depiction of a segment of memory configured according to an embodiment of the present invention in which an in-use memory area is tested by compressing the memory area contents and testing the area made available through such compression. FIG. 9 shows three depictions of memory, all of which are the same area of memory shown at different times. In the first depiction (top of FIG. 9), area 201 is designated for testing purposes and is there shown at a time prior to testing. However, the system presumably contains no free memory. Thus, in this example, memory must be compressed in order to perform testing.

In the second depiction (middle row of FIG. 9), compression is accomplished using the CRAM encoder/decoder as previously described to compress the in-use data of area 201 into a smaller area 203 and test the sub area 205. Here, there is also a non one-to-one correspondence and, therefore, multiple translation circuits are used to translate a single area to multiple areas. In this case, the address range depicted for area 201 is translated to two areas within area 203 by appropriate programming of lookup table 88 in a manner analogous to that described with reference to FIGS. 7 and 8, each of the two areas corresponding to half of the range of area 203. When serving OS memory references the data must be extracted and decompressed from area 203 or compressed and written to area 203 as previously described. Test memory references received from service processor 29 as part of the testing are routed directly to area 205 in this example. When the testing of area 205 completes, a portion of area 201 corresponding to area 203 remains untested and is tested next.

In the third depiction (bottom of FIG. 9), the untested portion of area 201 corresponding to the block shown at 207 is tested by moving the compressed data previously contained in area 203 to area 209 and servicing OS references from area 209 and directly routing test references to area 207 until completion of the testing.

Larger areas than any of the areas shown in the previous examples can be defined and tested using a combination of lookup table 88 translation circuits and arrays of translation circuits. Additionally, although in the preferred embodiment a service processor is used to perform the testing, in other embodiments the testing performed by service processor 29 can be performed by other processors in the system including but not limited to memory integrity processor 85. In an embodiment where memory integrity processor 85 performs this function, the need to implement sideband interface 83 and high-speed interface 21 is reduced or eliminated.

Several examples will now be shown and described which relate to mirrored-memory-subsystem embodiments such as shown in FIG. 2. For the most part, details concerning memory mirroring have been omitted in as much as such details are not necessary to obtain a complete understanding of the present invention and are within the skills of persons of ordinary skill in the relevant art. At the time of this writing, many industry standard chipsets provide support for memory mirroring and undue experimentation would not be required by one skilled in the art. A lookup table with the appropriate number of translation circuits is presumed in the examples below which require translation.

FIG. 10 is a block diagram of a mirrored memory subsystem according to an embodiment of the present invention in its normal mode of operation. In its normal mode of operation, two banks of memory 100 and 101 contain redundant data and half of the amount of physical memory is reported to the operating system as available for allocation. By default, SDRAM bank 100 is considered to be the active bank and SDRAM bank 101 is considered to be the mirrored bank. OS read references are serviced from SDRAM bank 100 whereas OS write references are written to both banks 100 and 101. The embodiment is therefore able to function in a standard memory mirroring configuration.

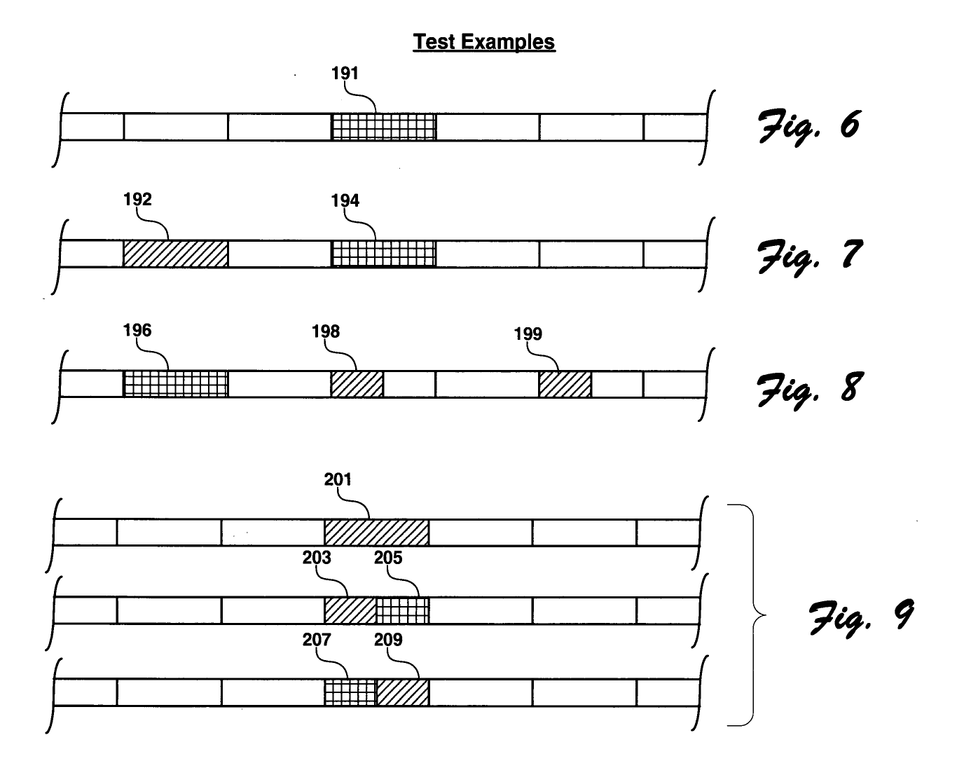

FIG. 11 is a block diagram of a mirrored memory subsystem according to an embodiment of the present invention wherein the mirroring is broken in order to test one of two memory banks. In this example, neither read references nor write references are serviced from main SDRAM bank 100. Instead, both read and write references are serviced from SDRAM bank 101. This frees up SDRAM bank 100 for testing by service processor 29. Since the embodiment had been in a memory mirroring configuration prior to breaking the mirror, the amount of memory reported to the operating system remains unchanged.

FIG. 12 is a block diagram of a mirrored memory subsystem according to an embodiment of the present invention in which the mirroring is maintained during the testing of one of two memory banks. In this example, OS read references are serviced from “mirrored” SDRAM bank 101. The data contained in SDRAM bank 100 is compressed into area 251 leaving area 252 available for testing by service processor 29. OS write references are written to both SDRAM bank 101 and compressed area 251 of SDRAM bank 100. The data written to area 251 of SDRAM bank 100 is translated by lookup table 88 and compressed by memory integrity processor 85 as previously described. In this way, testing is performed on “active” bank 100, although, effectively, the active bank in this mode is actually the bank that is normally considered to be the mirrored bank (bank 101). This is one example a mirrored memory subsystem which includes an active bank and a mirrored bank wherein system writes are directed to both banks and wherein system reads are serviced from the active bank during normal operation and from the mirrored bank during the test operation of the active bank.

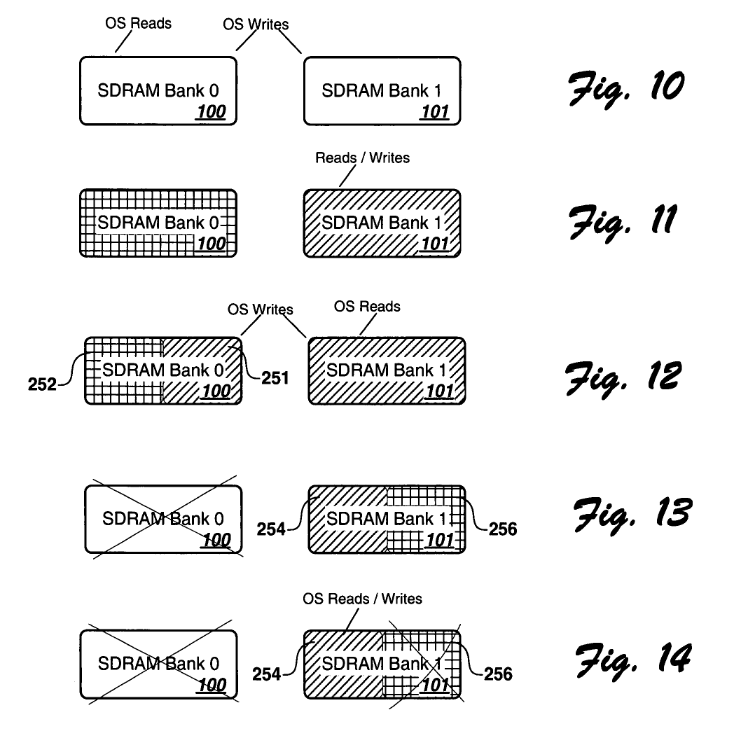

FIGS. 13-14 are block diagrams of a mirrored memory subsystem according to an embodiment of the present invention in which memory areas are found to be defective and in which an increased level of availability is provided through continuous verification of the remaining memory.

In the example shown in FIG. 13, SDRAM bank 100 is found to be entirely defective (for example, as a result of the testing described with respect to the prior figure and proceeding in response to such failure). A predictive failure report is provided to a management module of computer system (as previously described) to inform an administrator of the requirement for replacing “active” SDRAM bank 100. In this scenario, the memory mirroring is not broken. Instead, since the compression technology used approaches 2:1 and assuming some available memory in order to continuously move compressed data areas to unallocated areas in order to maintain continuous verification of memory in the manner previously described, the data taken from either the active bank or the mirrored bank is compressed and duplicated in areas 254 and 256 of FIG. 13. The memory mirroring is then maintained based on these two areas 254 and 256 acting as symmetrical active and mirrored banks. Area 254 can initially act as the active portion of the compressed mirror and area 256 can act as the mirrored portion. That is, initially, during a “normal” mode of operation, OS reads are serviced from compressed area 254, and, as is normal when mirroring, writes are written to both areas 254 and 256. The duplication can be accomplished, for example, by either compressing the data into area 254 and then copying this data into area 256, or by twice compressing the data, once each into areas 254 and 256.

Testing proceeds as previously described as long as the minimum amount of unallocated memory is available for testing of either the compressed active portion, area 254, or compressed mirrored portion, area 256. While the active portion is being tested, OS reads are serviced from mirrored portion, area 256, and vice versa.

The establishment of the compressed mirrored memory includes the utilization of either one of area 254 and area 256 as the active portion of the compressed mirrored memory and the other as the mirrored portion. The roles are swappable/switchable.

The example shown in FIG. 14 follows the scenario described in FIG. 13. This example presumes that an error occurred in area 256 during the testing described in FIG. 13, therefore now a fault condition exists in both banks of memory: the first in SDRAM bank 100 and the second in area 256 of SDRAM bank 101. According to this embodiment, the availability of the computer system is maintained given such a double failure. Memory controller 102, under the control of control circuitry 84 and memory integrity processor 85, breaks the mirror and operates out of area 254. A second failure signal is provided to the system administrator indicating the predictive failure of SDRAM bank 101. The system operates without the benefit of memory mirroring, however, availability is increased because it is able to continue to operate under a compressed mode of memory. Thus, system operation continues by servicing both read and write references from compressed portion 254.

In the above example, area 256 was taken to be the area having an error. However, in other examples, testing could be performed and errors found in area 254 and area 256 can provide the compressed area from which the computer system runs. Thus, a fault can be detected in any one of the active and mirrored portions. The compressed portion from which computer operation continues is the portion which is other than the portion in which the fall was detected.

In the above examples, the relocation, the servicing of memory references, and the passing of test data to the memory are performed without utilizing operating system resources. For example, operating system resources including virtual memory allocation resources, process resources, thread resources, and I/O resources are not used. Additionally, the relocation, the servicing, and the passage of test data are performed without utilizing main processor resources.

Embodiments of the present invention include various functions, which have been described above. The functions may be performed by hardware components or may be embodied in machine-executable instructions as firmware or software, which may be used to cause a general-purpose or special-purpose processor programmed with the instructions to perform the functions. Alternatively, the functions may be performed by a combination of hardware, firmware and software.

In the drawings and specifications there has been set forth a preferred embodiment of the invention and, although specific terms are used, the description thus given uses terminology in a generic and descriptive sense only and not for purposes of limitation.

What is claimed is:

1. Apparatus comprising:
a first memory area and a second memory area;
a main processor which runs an operating system from one or more of said first memory area and said second memory area; and
a memory controller which couples said main processor to said first memory area and said second memory area, the memory controller including processing capability which is which is able to operate in a mode which is alien to the operating system and is effective to:
relocate data contained in said first memory area to said second memory area;
service memory references directed to said first memory area from said second memory area; and
pass test data to said first memory area for testing at least a portion of said first memory area.

2. Apparatus according to claim 1 wherein the relocation, the servicing, and the passing of test data are performed without utilizing operating system resources.

3. Apparatus according to claim 2 wherein the operating system resources are resources selected from the group consisting of virtual memory allocation resources, process resources, thread resources, and I/O resources.

4. Apparatus according to claim 1 wherein the relocation, the servicing, and the passage of test data are performed without utilizing main processor resources.

5. Apparatus according to claim 1 wherein the test data is generated by a processor in the system which is a processor selected from the group consisting of a processor in the system which is other than said main processor and is external to said memory controller, and a processor included in said memory controller.

6. Apparatus according to claim 1 wherein said second memory area is a compressed area within said first memory area and wherein the test data is passed to an area within said first memory area which is other than the compressed area.

7. Apparatus according to claim 1 wherein said first memory area and said second memory area are areas within one or more banks of memory which form one of at least two mirrored memory areas of a mirrored memory, wherein the one of at least two mirrored memory areas are areas selected from the group consisting of an active area and a mirrored area of the mirrored memory.

8. Apparatus comprising:
a first memory area and a second memory area;
a main processor which runs an operating system from one or more of said first memory area and said second memory area;
a service processor which generates test data for testing one or more of said first memory area and said second memory area; and
a memory controller which couples said main processor and said service processor to said first memory area and said second memory area, the memory controller including a look-up table and an internal processor, the internal processor of said memory controller being effective to:
relocate data contained in said first memory area to said second memory area;
service memory references received from said main processor and directed to said first memory area by engaging the lookup table to translate addresses from said first memory area to said second memory area and servicing the references from said second memory area; and
pass test data generated by the service processor to at least a portion of said first memory area.

9. Apparatus according to claim 8 wherein the relocation, the servicing, and the passing of test data are performed without utilizing operating system resources.

10. Apparatus according to claim 9 wherein the operating system resources are resources selected from the group consisting of virtual memory allocation resources, process resources, thread resources, and I/O resources.

11. Apparatus according to claim 8 wherein the relocation, the servicing, and the passage of test data are performed without utilizing main processor resources.

12. Apparatus according to claim 8 wherein said second memory area is a compressed area within said first memory area and wherein the test data is passed to an area within said first memory area which is other than the compressed area.

13. Apparatus according to claim 8 wherein said first memory area and said second memory area are areas within one or more banks of memory which form one of at least two mirrored memory areas of a mirrored memory, wherein the one of at least two mirrored memory areas are areas selected from the group consisting of an active area and a mirrored area of the mirrored memory.

14. A method comprising:
relocating data contained in a first memory area to a second memory area;
servicing memory references directed to the first memory area from the second memory area; and
testing at least a portion of the first memory area.

15. The method of claim 14 wherein said relocation, said servicing, and said testing are performed without utilizing operating system resources.

16. The method of claim 15 wherein the operating system resources are resources selected from the group consisting of virtual memory allocation resources, process resources, thread resources, and I/O resources.

17. The method of claim 14 wherein said relocation, said servicing, and said testing are performed without utilizing main processor resources.

18. The method of claim 14 wherein the second memory area is a compressed area within the first memory area and wherein said testing includes a test of an area within the first memory area which is other than the compressed area.

19. The method of claim 14 wherein the first memory area and the second memory area are areas within one or more banks of memory which form one of at least two mirrored memory areas of a mirrored memory, wherein the one of at least two mirrored memory areas are areas selected from a group consisting of an active area and a mirrored area of the mirrored memory.

20. A method comprising:
determining a fault condition in a failed bank, which can be any of an active bank and an mirrored bank, of a mirrored memory subsystem included in a computing system during a test operation of the failed bank, the mirrored memory subsystem including the failed bank and a working bank which is the mirrored counterpart of the failed bank wherein system writes are directed to both banks, and wherein system reads are primarily serviced from either bank during normal operation and from the working bank during the test operation of the failed bank;
generating a first failure signal which identifies a fault in relation to the failed bank;
compressing the data in the working bank into a first area within the working bank;
duplicating the compressed data into a second area within the working bank; and
establishing a compressed mirrored memory within the working bank using the first area and the second area as corresponding symmetrical mirrored memories.

21. The method of claim 20 wherein said establishment of the compressed mirrored memory includes the utilization of one of the first area and the second area as the active portion of the compressed mirrored memory and the other as the mirrored portion.

22. The method of claim 21 wherein system writes are directed to the active, and mirrored, portions and wherein system reads are serviced from the active portion during normal operation and from the mirrored portion during a test operation of the active portion.

23. The method of claim 22 wherein the utilization, of one of the first area and the second area as the active portion of the compressed mirrored memory and the other as the mirrored portion, is switchable such that either area can be utilized as either portion.

24. The method of claim 23 further comprising:
upon a fault being detected in any one of the active and mirrored portions,
breaking said establishment of the compressed mirrored memory;
generating a second failure signal in relation to the mirrored bank; and
continuing system operation by servicing read and write references from a compressed portion which is other than the portion for which the fault was detected.
